(19) United States
(12) Patent Application Publication
(10) Pub. No.: US 2019/0296709 A1
(43) Pub. Date: Sep. 26, 2019

(54) IMPEDANCE MATCHING CIRCUITRY

(71) Applicant: SOFANT TECHNOLOGIES LTD, Edinburgh (GB)

(72) Inventors: Ahmed Osman EL-RAYIS, Edinburgh (GB); Yan Chiew WONG, Edinburgh (GB); Tughrul Sati ARSLAN, Grange, Edinburgh (GB)

(21) Appl. No.: 16/306,245

(22) PCT Filed: May 31, 2016
(86) PCT No.: PCT/GB2016/051590

§ 371 Date: Nov. 30, 2018

(30) Foreign Application Priority Data
Jun. 26, 2015 (GB) 1511273.3

(51) Int. Cl. H03H 7/38; H01P 3/08

(52) U.S. Cl. CPC H03H 7/383; H01P 3/081

(57) ABSTRACT

The invention provides impedance matching circuitry for adjusting an impedance match between a source impedance (2) and a load impedance (4), the impedance matching circuitry comprising: tapered transmission line circuitry which comprises one or more tapered transmission lines (10) coupled or couplable between the source impedance and the load impedance; and a controller (20) in communication with the tapered transmission line circuitry and configured to adjust one or more impedances of the tapered transmission line circuitry to thereby adjust an impedance match between the source impedance and the load impedance.

### FIELD OF THE INVENTION

The invention relates to (typically broadband, typically tuneable) impedance matching circuitry, circuitry comprising (typically broadband, typically tuneable) impedance matching circuitry and a method of adjusting (typically improving) an impedance match between a source impedance and a load impedance.

### BACKGROUND TO THE INVENTION

Impedance matching between source and load impedances is important to optimise the efficiency of power transfer between the source and the load in some microwave and Radio Frequency (RF) circuits. For the transfer of maximum power between a source and a load, the complex impedance looking towards the source must be a complex conjugate of the load impedance. This minimises signal reflections at the input terminals of the load, maximising the signal that can be transferred from the source to the load. Impedance matching is also used for improving the sensitivity of RF receivers, reducing the amplitudes and phase imbalances in power distributions, minimising power loss in feed lines and protecting power amplifiers from damage due to reflected power from its output terminals.

Typically impedance matching is achieved by inserting an impedance matching network between the source and the load. For some applications, the source and load impedances remain constant, in which case fixed impedance matching networks are sufficient. However, for other applications, the source and/or load impedances are subject to change, in which case it is necessary for the impedance matching network to be reconfigurable so that an impedance match can be achieved when changes in the source and/or load impedance occur. An example of the latter is impedance matching provided between the RF front-end and an antenna of wireless communications devices such as mobile smartphones, tablets and phablets. RF front-ends of such wireless communications devices are typically designed using a 50Ω antenna impedance load, for which (in theory) maximum efficiency, operation time, quality of link and maximum lifetime are obtained. In practice, however, many factors (such as the interaction of a human hand with the antenna) can cause a change from the 50Ω load seen by the RF front end to a capacitive or inductive load. This results in poor signal reception, generates heat and unproductively uses up battery power.

Several different methods of impedance matching are available. One such method is to provide a quarter-wave transformer between a source and a real load impedance to (at least theoretically) provide a perfect impedance match with zero signal reflections at the interface between the source and the load at a single frequency. In practice, however, impedance matching typically needs to be effective across a wider range of frequencies. Moreover, quarter-wave transformers are not reconfigurable.

A broader bandwidth solution is the multi-section transformer comprising a plurality of transformer sections connected in series, each section having the same electrical length. If the sections of transmission line are extremely small, a multi-section transformer can be considered to be a continuous tapered transmission line. Continuous tapered transmission lines typically have an end coupled to the source and an end coupled to the load, and the impedance of the continuous tapered transmission line varies from the end coupled to the source (at which point the impedance of the tapered transmission line is typically equal to an output impedance of the source) to the end coupled to the load (at which point the impedance of the tapered transmission line is typically equal to an input impedance of the load) in accordance with a taper function (e.g. an exponential or Klopfenstein function). In addition, adjoining sections of the continuous tapered transmission lines are typically provided with characteristic impedances which vary only slightly so that the signal reflections between adjoining sections are minimal. This design ensures that there are impedance matches between the source and the tapered transmission line, between the tapered transmission line and the load and near impedance matches between adjacent sections of the tapered transmission line.

An advantage of continuous tapered transmission lines is that they have broadband frequency responses. However, tapered transmission lines can only match real impedances. Furthermore, tapered transmission lines do not have tuning capabilities which would enable them to be used in applications requiring reconfigurable impedance matching networks.

Other impedance matching networks include single component matching networks, typically implemented by a variable length of microstrip line or a variable capacitive or inductive lump element. However, such networks are not particularly suitable for reconfigurable impedance matching networks. Impedance matching networks having two or more (typically tuneable) reactive elements are typically more suitable for reconfigurable impedance matching networks, but such networks can typically be provided with either a high quality (Q) factor and a low bandwidth, or a low quality (Q) factor and a high bandwidth. This restriction can be overcome to an extent by including a third (typically tuneable) reactive component (and optionally further additional components) in the impedance matching network, but the (typically tuneable) reactive components are also typically narrow-banded and therefore do not offer wide enough bandwidths for some applications.

One way of achieving reconfigurable impedance matching over a wide bandwidth is to provide impedance matching circuitry comprising a plurality of narrow band reconfigurable impedance matching networks (e.g. pi networks), one for each of a corresponding plurality of frequency bands, and to selectively connect and configure one of the plurality of narrow band reconfigurable impedance matching networks (e.g. pi networks) between the source impedance and the load impedance responsive to a determination of the frequency of signal propagating from the source to the load. However, this approach requires a large set of potential component values for the matching network and means pre-calculating a high number of potential values of the tuneable reactive components for each frequency band. For applications (e.g. an antenna) which are required to operate over a wide range of frequencies, a very large set of tuning data would be required for the matching network. Generating this data would require an unfeasibly large number of calculations as an initialisation procedure for such impedance matching circuitry.

Due to the lack of a suitable impedance matching solution, mismatches between source and load impedances are often overlooked in broadband systems, but such impedance mismatches can be the limiting factor in the performance of such systems, particularly when the impedance of the source or the load changes. Accordingly, the design of new reconfigurable impedance matching network which is more suitable for broadband applications would be desirable.

### SUMMARY OF THE INVENTION

A first aspect of the invention provides (typically reconfigurable) impedance matching circuitry for adjusting (typically improving) an (e.g. complex) impedance match between a source impedance and a load impedance, the impedance matching circuitry comprising: tapered transmission line circuitry which comprises one or more (preferably continuously) tapered transmission lines coupled or (e.g. selectively) couplable (e.g. serially) between the source impedance and the load impedance; and a controller in communication with the tapered transmission line circuitry and configured to adjust one or more impedances (typically including one or more reactances) of the tapered transmission line circuitry to thereby adjust (typically improve) an impedance match between the source impedance and the load impedance.

By providing the impedance matching circuitry with one or more tapered transmission lines, the impedance matching circuitry is provided with a broadband frequency response. This makes the impedance matching circuitry particularly suitable for applications where signals of different frequencies are required to propagate between the source (comprising the source impedance) and the load (comprising the load impedance). By providing the impedance matching circuitry with a controller in communication with the tapered transmission line circuitry and configured to adjust one or more impedances (typically including one or more reactances) of the tapered transmission line circuitry, the impedance matching circuitry can be reconfigured to take into account changes in the source impedance and/or load impedance, thereby allowing an impedance match to be achieved between the source and load impedances under different operating conditions.

For example, the load may comprise an antenna module comprising one or more antennae (in which case the load impedance may comprise an input impedance of the antenna module). In this case (e.g. RF) electromagnetic waves of different frequencies may be required to propagate from the source to the load to enable the antenna module to transmit (e.g. RF or microwave) electromagnetic waves of different frequencies (e.g. in different operating modes), and it may be that the source and/or load impedances are frequency dependent. In this case, adjusting the impedance(s) of the tapered transmission line circuitry allows an impedance match to be achieved between the source and load impedances at each operating frequency. Additionally or alternatively, interaction between a user and one or more antennae of the antenna module (which antennae may be part of the casing of a wireless communications device used by the user) can alter the (e.g. input) impedance (typically including the reactance) of the antenna module, in which case adjusting the impedance(s) of the tapered transmission line circuitry ensures that an impedance match is achieved even when the impedance of the antenna module changes due to changes in the way in which the user is interacting with the antenna module.

Providing broadband impedance matching circuitry also reduces the number of search states and the reconfigurations of the impedance matching circuitry required to achieve an impedance match between the source impedance and the load impedance, particularly for multi-mode operation (because a single impedance state can be re-used for a plurality of frequencies). The impedance matching circuitry can be highly efficient with very low insertion loss over a broad range of mismatch loads and frequency ranges.

By a “tapered transmission line” we mean a transmission line having a characteristic impedance which varies (preferably continuously) gradually along its length in accordance with a taper function between a first impedance at a first end and a second impedance at a second end (typically such that the signal reflections from intermediate portions of the transmission line between the first and second ends are minimal). It may be that the taper function is implemented by physically (preferably continuously) tapering one or more dimensions of a conductor of the transmission line along which signals propagate between the source and the load (e.g. (preferably continuously) increasing or decreasing the thickness and/or width of the conductor along its length in accordance with said taper function). Additionally or alternatively, it may be that the taper function is implemented by (typically continuously) tapering the permittivity of a substrate on which the (conductor of the) transmission line is mounted in accordance with a taper function (e.g. the substrate may be provided between the conductor of the transmission line and ground). Typically the taper is continuous along the (entire, or at least 80% of, preferably at least 90% of the) length of the transmission line. However, at a micro scale, there may be some discontinuities (e.g. steps) along the tapered transmission line due to an imperfect manufacturing process of the taper. It may be that the tapered transmission line is formed from a plurality of discrete sections (e.g. microstrip layers) coupled together in series, in which case each of the discrete sections typically has an electrical length of less than a quarter of the wavelength of electromagnetic signals propagating along it from the source to the load in use.

Typically each of the tapered transmission line(s) typically comprises a lower impedance end and a greater impedance end (i.e. the greater impedance end having an impedance which is greater than the impedance of the lower impedance end).

It will be understood that the term “source impedance” is not intended to be limited to an impedance of an original source (e.g. signal generator), but rather the term “source” includes an intermediate source (e.g. a circuitry stage from which (e.g. RF or microwave) signal power propagates to the load, such as a modulator, amplifier, filter, phase shifter) even if the intermediate source propagates electromagnetic signal power from an original source (e.g. signal generator). Similarly, by “load impedance” we include an (e.g. input) impedance of an intermediate load (e.g. filter, amplifier, phase shifter) even if that intermediate load propagates electromagnetic signal power to an ultimate load.

It may be that the controller is configured to adjust the said one or more impedances of the tapered transmission line circuitry to thereby adjust one or more characteristic impedances of a said tapered transmission line coupled between the source impedance and the load impedance. It may be that the controller is configured to adjust the said one or more impedances of the tapered transmission line circuitry to thereby adjust an input impedance and/or an output impedance of the tapered transmission line circuitry. By the “input impedance” of the tapered transmission line circuity we mean the impedance of the tapered transmission line circuitry as seen by the source impedance. By the “output impedance” of the tapered transmission line circuitry we mean the impedance of the tapered transmission line circuitry as seen by the load impedance.

Typically the controller is configured to adjust one or more impedances of the tapered transmission line circuitry by way of a (e.g. electronic current and/or voltage) control signal. For example, the controller may be configured to adjust one or more impedances of the tapered transmission line circuitry by providing a control signal to activate or de-activate one or more switches of the tapered transmission line circuitry. Additionally or alternatively, the controller may be configured to adjust one or more impedances of the tapered transmission line circuitry by providing a control signal to adjust the impedance(s) of one or more tuneable (e.g. active or reactive) components (or groups of components) of the tapered transmission line circuitry (each of the one or more tuneable components or groups of components typically having an impedance which is controllable by the controller).

For example, it may be that the tapered transmission line circuitry comprises two or more (typically different) tapered transmission lines selectively couplable between the source impedance and the load impedance. It may be that the tapered transmission line circuitry comprises one or more switches for selectively coupling one or more of the said plurality of tapered transmission lines between the source impedance and the load impedance. For example, it may be that each of the plurality of tapered transmission lines is coupled to a respective switch for selectively coupling that tapered transmission line between the source impedance and the load impedance. The said switches are typically provided in communication with (and the opening and closing of the switches is typically under the control of) the controller. In this case, it may be that the controller is configured to adjust one or more impedances of the tapered transmission line circuitry by selectively coupling one or more (typically a sub-set, e.g. a single one) of the plurality of tapered transmission lines between the source and the load impedances. It may be that two or more (or each) of the plurality of tapered transmission lines have characteristic impedances which vary along their lengths according to different taper functions.

Additionally or alternatively, it may be that the tapered transmission line circuitry comprises tuneable impedance circuitry (which is typically coupled to a said tapered transmission line), and the controller is configured to adjust one or more impedances of the tuneable impedance circuitry to thereby adjust an impedance match between the source impedance and the load impedance. Typically, the tuneable impedance circuitry (where provided) has an impedance (typically including a reactance) which is tuneable responsive to a control signal provided by the controller.

The tuneable impedance circuitry may comprise one or more tuneable (typically active or reactive) components having individually tuneable impedances. For example, the tuneable impedance circuitry may comprise one or more tuneable capacitors, inductors and/or couplings capable of adjusting the impedance mismatch between the source and load impedances. Typically the controller is configured to control the impedances of the tuneable components by way of voltage and/or current control signals. It may be that the impedance matching circuitry comprises one or more tuneable (typically active or reactive) components (which are typically coupled to a said tapered transmission line, and each of the one or more tuneable components typically have an impedance which is controllable by the controller), the controller being configured to adjust an impedance (typically including a reactance) of one or more (or two or more or each) of the said tuneable (typically active or reactive) component(s) to thereby adjust the impedance match between the source impedance and the load impedance.

It may be that the tuneable impedance circuitry comprises one or more (e.g. a plurality of) tuneable reactive components, each of the said tuneable reactive components having a capacitance or an inductance which is tuneable by way of a (e.g. current and/or voltage) control signal provided by the controller.

It may be that the tuneable impedance circuitry comprises a tuneable reactive component connected in series with the said tapered transmission line. It may be that two or more tuneable reactive components of the tuneable impedance circuitry are connected in series with each other.

It may be that the tuneable impedance circuitry comprises a tuneable reactive component connected in parallel with the said tapered transmission line. It may be that two or more tuneable reactive components of the tuneable impedance circuitry are connected in parallel with each other.

The one or more tuneable reactive components may comprise one or more MEMS capacitors (e.g. as disclosed in international patent publication number WO2008/152428 which is incorporated in full herein by reference) or one or more groups of MEMS capacitors having a capacitance which varies linearly responsive to a linearly varying voltage and/or current control signal provided by the controller.

It may be that the tuneable impedance circuitry comprises one or more groups of components, each of the one or more groups having an overall impedance (typically including a reactance) which can be current and/or voltage controlled. For example, the tuneable impedance circuitry may comprise a bank of switched (e.g. micro-electro-mechanical systems (MEMS)) capacitors (e.g. as disclosed in WO2008/152428) selectively connectable in parallel with each other. It may be that the impedance of the bank of switched capacitors is tuneable by selecting which capacitors of the bank of capacitors are connected in parallel, for example by opening or closing capacitor switches to activate or deactivate capacitors within the bank. Typically whether the capacitor switches are opened or closed is controlled by a voltage and/or current control signal provided by the controller. It may be that individual capacitors within the bank are tuneable (e.g. MEMS) capacitors having capacitances which are individually tuneable. Again, in this case, the tuneable capacitors typically have capacitances which are individually tuneable by a voltage and/or current control signal provided by the controller (e.g. linearly, as above).

Typically the tuneable impedance circuitry is coupled to a said tapered transmission line (or to one or more said tapered transmission lines) such that varying the impedance of the tuneable impedance circuitry causes a variation of an (e.g. input and/or output) impedance of the tapered transmission line circuitry.

It may be that at least part of the tuneable impedance circuitry is coupled to the said tapered transmission line directly (e.g. it may be that there is a physical join or a length of conductor between the tuneable impedance circuitry and the tapered transmission line, typically without any other active or reactive components provided between the tuneable impedance circuitry and the tapered transmission line). It may be that at least part of the tuneable impedance circuitry is coupled to the said tapered transmission line indirectly (e.g. it may be that there are active or reactive components provided between the tuneable impedance circuitry and the tapered transmission line). It may be that at least part of the tuneable impedance circuitry is connected to a component having a fixed capacitance/inductance (e.g. a fixed capacitive or inductive element such as a stub) which is in turn connected (typically directly) to the said tapered transmission line. Where the component having the fixed capacitance/inductance comprises a stub, it may be that the tuneable impedance circuitry is connected to one end of the stub or it may be that the tuneable impedance circuitry is connected to an intermediate portion of the stub between (typically opposite) first and second ends of the said stub.

It may be that at least part of the tuneable impedance circuitry is incorporated into a said tapered transmission line.

Typically the at least part of the tuneable impedance circuitry incorporated into the said tapered transmission line comprises one or more tuneable (typically active or reactive) components.

The tuneable components may, for example, comprise a semiconductor varactor, a MEMS varactor, a PIN diode, RF MEMS capacitor or inductor, transistor, tuneable lump (typically inductive or capacitive) components or any other component capable of implementing an impedance (typically including a reactance) which is variable responsive to a current and/or voltage control signal. Preferably, the one or more tuneable reactive components incorporated into the tapered transmission line are tuneable MEMS reactive components (e.g. micro-electro-mechanical systems (MEMS) capacitors, e.g. as disclosed in WO2008/152428).

It may be that at least part of the tuneable impedance circuitry is connected to the tapered transmission line at an intermediate position along the length of the tapered transmission line. It may be that at least part of the tuneable impedance circuitry is connected to the tapered transmission line at an end thereof. It may be that another part of the tuneable impedance circuitry is connected to the tapered transmission line at a different end thereof.

It may be that the controller is configured to adjust the impedance match between the source impedance and the load impedance by adjusting the load impedance as seen by the source (e.g. through the impedance matching circuitry) to bring it closer to the complex conjugate of the source impedance (or closer to the source resistance, if the source impedance is purely real).

Typically the controller is configured to adjust the impedance match between the source impedance and the load impedance by adjusting one or more impedances (typically including one or more reactances) of the tapered transmission line circuitry to thereby adjust an output impedance of the impedance matching circuitry such that it is closer to or equals a complex conjugate of the load impedance.

It may be that the controller is configured to adjust the impedance match between the source impedance and the load impedance by adjusting one or more impedances (typically including one or more reactances) of the tapered transmission line circuitry to thereby adjust an input impedance of the impedance matching circuitry such that it is closer to or equals a complex conjugate of the source impedance (or closer to the source resistance, if the source impedance is purely real).

It may be that the controller comprises (or is provided in communication with) a memory storing a look-up table. The said look-up table typically comprises a plurality of predetermined impedance configurations. It may be that each of the said plurality of predetermined impedance configurations is associated with one or more conditions such as one or more frequency conditions and/or one or more impedance mismatch conditions. It may be that the controller is configured to determine whether the said one or more conditions are met and to adjust one or more impedances of the tapered transmission line circuitry in accordance with a selected impedance configuration from the plurality of impedance configurations responsive to a determination that the said one or more conditions have been met. Typically the conditions comprise one or more frequency conditions which relate to a (e.g. microwave or radio) frequency of signals being propagated from the source (i.e. the source comprising the source impedance) to the load (i.e. the load comprising the load impedance).

In a particular example, the impedance matching circuitry may be provided on a wireless communications device such as a mobile smartphone, wearable personal communications device or accessory, tablet or phablet. In this case, it may be that the controller is provided in communication with baseband circuitry configured to provide the controller with frequency information relating to a (e.g. RF or microwave) frequency at which the wireless communications device is communicating (typically transmitting and/or receiving). The controller is typically configured to receive the said frequency information from the baseband circuitry and to select an impedance configuration (from the plurality of impedance configurations) associated with the frequency information obtained from the baseband circuitry.

It may be that the tuneable impedance circuitry comprises one or more tuneable impedance modules, each of the said tuneable impedance modules having an impedance which is tuneable by the controller. It will be understood that the tuneable impedance modules may have any, or any combination, of the preferred and optional features discussed herein in respect of the tuneable impedance circuitry.

It may be that the tuneable impedance circuitry comprises a first tuneable impedance module connected to the tapered transmission line at a first (e.g. intermediate) position along its length and a second tuneable impedance module connected to the tapered transmission line at a second (e.g. intermediate) position along its length different from the first position.

An impedance mismatch sensor may be provided which is configured to detect an impedance mismatch between the source impedance and the load impedance, the impedance mismatch sensor being in communication with the controller.

It may be that the impedance mismatch sensor is connected to one or both of the source impedance and the load impedance.

It may be that the controller is configured to adjust the said one or more impedances of the tapered transmission line circuitry to thereby adjust the impedance match between the source impedance and the load impedance responsive to a determination by the controller from the impedance mismatch sensor of an impedance mismatch between the source impedance and the load impedance.

Typically the controller is configured to iteratively adjust the said one or more impedances of the tapered transmission line circuitry to thereby adjust the impedance match between the source impedance and the load impedance until the controller determines from the impedance mismatch sensor that there is an impedance match between the source impedance and the load impedance (optionally after an initial adjustment in accordance with a configuration obtained from a or the look-up table).

Typically the controller is configured to receive an impedance mismatch condition from the impedance mismatch sensor, and to select (and typically apply to the impedance matching circuitry) an impedance configuration (from the plurality of impedance configurations) associated with the impedance mismatch condition.

As indicated above, it may be that each of the one or more tapered transmission lines is formed from a continuously tapering conductor (e.g. the physical thickness or width is continuously tapering along the length of the conductor or the permittivity of the substrate on which the transmission line is mounted continuously tapers along its length). More typically, the (or each) tapered transmission line circuitry includes a tapered transmission line comprising a plurality of discrete sections (e.g. microstrip layers) coupled together (typically in series). It may be that one or more or each of the discrete sections is individually tapered. Alternatively it may be that one or more or each of the discrete sections is of constant width along its length (i.e. is not individually tapered), in which case it may be that the taper is achieved by providing adjacent discrete sections with widths or thicknesses which increase gradually along the length of the tapered transmission line with each successive section. It will be understood that the thickness or width of the tapered transmission line may be constant along its length and that the taper is achieved by tapering the permittivity of the substrate on which the transmission line is mounted. Typically the electrical length of each discrete section is less than a quarter of the wavelength of electromagnetic signals propagating along them in use.

Typically the said discrete sections comprise stepped piecewise transmission lines.

To optimise the impedance match (and therefore maximise signal power transfer) between the source and the load impedances, it is typically necessary for the discrete sections of the tapered transmission line to have the same or substantially the same electrical lengths as each other. The electrical length of a transmission line is a function of signal frequency (as well as material, dimensions etc.). Accordingly when the frequency of electromagnetic waves propagating from the source to the load changes, the electrical lengths of the discrete sections of the tapered transmission line also change. Thus, the sections of the tapered transmission line are typically provided with electrical lengths which have substantially linear frequency responses, that is, the electrical length of each section changes linearly with operating frequency, at least in a frequency range comprising a design operating frequency. Typically the electrical lengths of each of the sections of the tapered transmission line change in substantially the same way as each other as a function of frequency, at least in a frequency range comprising a design operating frequency. Thus, the electrical lengths of the discrete sections of the tapered transmission line have the same or substantially the same electrical lengths as each other over a range of operating frequencies, albeit the actual electrical lengths may be different for different operating frequencies.

The electrical lengths of the discrete sections are also functions of phase velocity, which is in turn a function of the inductance and capacitance of the said sections of the tapered transmission line. It may be that each of one or more (or each) of the discrete sections is provided with a constant phase velocity along its length for a particular operating frequency.

It may be that one or each of a plurality (or each) of the said discrete sections is coupled to a (different) respective tuneable impedance module of the tapered transmission line circuitry, the controller being configured to adjust an impedance of one or more (or two or more or each) of the said tuneable impedance modules to thereby adjust the impedance match between the source impedance and the load impedance.

Preferably, each of the discrete sections of the tapered transmission line is coupled to a (typically different) tuneable impedance module of the tapered transmission line circuitry.

It may be that the controller is configured to adjust the impedances of the tuneable impedance modules coupled to the discrete sections to thereby improve the impedance match between the source impedance and the load impedance.

It may be that the respective tuneable impedance modules are connected to the discrete sections of the tapered transmission line at positions distributed along the length of the tapered transmission line.

The tapered transmission line circuitry may comprise a first tapered transmission line and a second tapered transmission line. It may be that the first tapered transmission line is connected or connectable in series with the second tapered transmission line. The tapered transmission line circuitry may comprise a first tuneable impedance module coupled to the first tapered transmission line and a second tuneable impedance module coupled to the second tapered transmission line. Typically the controller is configured to adjust an impedance of a selected one (or both) of the first and second tuneable impedance modules to thereby adjust the impedance match between the source and the load impedances.

It will be understood that the tuneable impedance modules typically have impedances (typically including one or more reactances) which are (typically independently) adjustable by the controller (typically to thereby adjust the impedance match between the source impedance and the load impedance).

The first and second tapered transmission lines may be symmetrically configured. For example, the first and second tapered transmission lines may be connected back-to-back (i.e. the lower impedance (e.g. wider) end of the first tapered transmission line is connected to the lower impedance end of the second transmission line). Configuring the first and second tapered transmission lines symmetrically typically makes it easier to interface the impedance matching circuitry with existing (e.g. test) equipment (such as a network analyser).

Alternatively, the first and second tapered transmission lines may be asymmetrically configured. For example, the first and second tapered transmission lines may be connected front-to-back (i.e. the greater impedance (e.g. narrower) end of the first tapered transmission line is connected to the lower impedance end of the second transmission line) or front-to-front (i.e. the greater impedance (e.g. narrower) end of the first tapered transmission line is connected to the greater impedance end of the second transmission line).

The first tuneable impedance module may be connected directly to the first tapered transmission line (e.g. at one end of the first tapered transmission line or at an intermediate portion of the first tapered transmission line along its length between opposing ends thereof). The second tuneable impedance module may be connected directly to the second tapered transmission line (e.g. at one end of the second tapered transmission line or at an intermediate portion of the second tapered transmission line along its length between opposing ends thereof).

The first and second tapered transmission lines may be identical to each other. Alternatively, it may be that the first and second tapered transmission lines may be different. For example, the first and second tapered transmission lines may have characteristic impedances which vary along their length in accordance with different taper functions.

It may be that the controller is configured to selectively adjust an impedance of the first tuneable impedance module to thereby adjust the impedance match between the source impedance and the load impedance in respect of (e.g. responsive to a determination that the) signals propagating between the source and the load having (have) a frequency within a first frequency range, and the controller is configured to selectively adjust an impedance of the second tuneable impedance module to thereby adjust the impedance match between the source impedance and the load impedance in respect of (e.g. responsive to a determination that the) signals propagating between the source and the load having (have) a frequency within a second frequency range different from the first frequency range.

It may be that the first and second tapered transmission lines have different structures, the structure of the first tapered transmission line being suitable for improving the impedance match between the source impedance and the load impedance for electromagnetic signals in the first frequency range and the second tapered transmission line being suitable for improving the impedance match between the source impedance and the load impedance for electromagnetic signals in the second frequency range.

It may be that the first and second tapered transmission lines are configured such that electromagnetic waves propagating from the source impedance to the load impedance propagate along both the first and second tapered transmission lines whether the frequency of the electromagnetic waves are in the first frequency range or the second frequency range. It may be that when the frequencies of the said electromagnetic waves are in the first frequency range, the controller is configured to adjust an impedance of the first tuneable impedance module to thereby adjust the impedance match between the source and load impedances. It may be that when the frequencies of the said electromagnetic signals are in the second frequency range, the controller is configured to adjust an impedance of the second tuneable impedance module to thereby adjust the impedance match between the source and load impedances.

Alternatively it may be that the first and second tapered transmission lines are selectively couplable between the source and load impedances such that electromagnetic signals propagating from the source impedance to the load impedance propagate along (typically only) one of the first and second tapered transmission lines depending on whether the frequency of the electromagnetic waves is in the first frequency range or the second frequency range. It may be that the impedance matching circuitry comprises (first) by-pass circuitry configured such that electromagnetic waves of a frequency within the first frequency range propagate from the source impedance to the load impedance by way of the first tapered transmission line and the (first) by-pass circuitry, by-passing the second tapered transmission line. It may be that the impedance matching circuitry comprises (second) by-pass circuitry configured such that electromagnetic waves of a frequency within the second frequency range propagate from the source impedance to the load impedance by way of the second tapered transmission line and the (second) by-pass circuitry, by-passing the first tapered transmission line. Thus, the first tapered transmission line can be provided with a first taper function which is suitable for improving the impedance match between the source and the load at a first operating frequency (or within a first operating frequency range) and the second tapered transmission line can be provided with a second taper function which is suitable for improving the impedance match between the source and the load at a second operating frequency (or within a second operating frequency range) different from the first. For example, it may be that the electrical lengths of a plurality of discrete sections of the first tapered transmission line are equal (or at least substantially equal) to each other when the operating frequency is within the first operating frequency range and the electrical lengths of a plurality of discrete sections of the second tapered transmission line are equal (or at least substantially equal) to each other when the operating frequency is within the second operating frequency range.

It may be that the tapered transmission line circuitry comprises a tuneable impedance module connected (e.g. in series or in parallel) between the first and second tapered transmission lines. It may be that the controller is configured to adjust an impedance of the said tuneable impedance module to thereby adjust the impedance match between the source impedance and the load impedance.

It may be that the tapered transmission line circuitry comprises a quarter wavelength transformer connected to (e.g. in series with) a said tapered transmission line of the tapered transmission line circuitry (e.g. between a first tapered transmission line and a second tapered transmission line of the tapered transmission line circuitry which may be connected in series with each other).

Providing a quarter wavelength transformer connected to one or more tapered transmission lines can provide more flexibility in the design of the impedance matching circuitry, a quarter wavelength transformer (typically only) being able to help with the correction of the real part of an impedance mismatch.

Typically the source impedance is connected to the load impedance by way of the tapered transmission line circuitry. Typically the source impedance is connected to the load impedance by way of one or more tapered transmission lines of the tapered transmission line circuitry.

It will be understood that the controller could be implemented in hardware, in software or in a combination of hardware and software. In one example, the controller comprises a processor, such as a microprocessor or microcontroller, implementing instructions defined by a computer program running on the said processor. It may be that the controller comprises a computer processing system having one or more computer processors, the computer processing system being configured to perform the steps performed by the controller.

A second aspect of the invention provides circuitry comprising: a source having a source impedance; a load coupled to the source, the load having a load impedance; and (typically reconfigurable) impedance matching circuitry according to the first aspect of the invention (e.g. serially) coupled between the source impedance and the load impedance.

A third aspect of the invention provides a method of adjusting (typically improving) an impedance match between a source impedance and a load impedance, the method comprising: (typically serially) coupling tapered transmission line circuitry comprising one or more tapered transmission lines between the source impedance and the load impedance; and adjusting one or more impedances (typically including one or more reactances) of the tapered transmission line circuitry to thereby adjust (typically improve) an impedance match between the source impedance and the load impedance.

Typically the method comprises adjusting an impedance of tuneable impedance circuitry (which is typically coupled (typically directly or indirectly) to a tapered transmission line) of the tapered transmission line circuitry to thereby adjust (typically improve) the impedance match between the source impedance and the load impedance.

It may be that the method comprises adjusting an impedance (e.g. including a reactance) of one or more tuneable (e.g. active or reactive) components (typically coupled to one or more tapered transmission lines) of the tapered transmission line circuitry to thereby adjust (typically improve) the impedance match between the source impedance and the load impedance.

It may be that the method comprises adjusting one or more impedances (typically including one or more reactances) of the tapered transmission line circuitry to thereby adjust an output impedance of the tapered transmission line circuitry such that it is closer to or equals a complex conjugate of the load impedance.

It may be that the method comprises adjusting one or more impedances (typically including one or more reactances) of the tapered transmission line circuitry to thereby adjust an input impedance of the tapered transmission line circuitry such that it is closer to or equals a complex conjugate of the source impedance.

It may be that the method comprises adjusting the load impedance as seen by the source (e.g. through the impedance matching circuitry) to bring it closer to the complex conjugate of the source impedance (or closer to the source resistance, if the source impedance is purely real).

It may be that the method comprises determining a frequency of electromagnetic waves propagating from the source impedance to the load impedance and adjusting one or more impedances of the tapered transmission line circuitry taking into account the determined frequency to thereby adjust (typically improve) the impedance match between the source impedance and the load impedance. Typically the method comprises comparing the determined frequency with a look-up table which associates each of a plurality of impedance configurations with one or more frequencies; selecting an impedance configuration from the plurality of impedance configurations, the selected impedance configuration being associated with the determined frequency in the look-up table; and adjusting one or more impedances of the of the tapered transmission line circuitry in accordance with the selected impedance configuration.

The method may further comprise detecting an impedance mismatch between the source impedance and the load impedance.

The method may further comprise adjusting the said one or more impedances of the tapered transmission line circuitry to thereby adjust the impedance match between the source impedance and the load impedance responsive to a determination of an impedance mismatch between the source impedance and the load impedance.

Typically the method comprises iteratively adjusting the said one or more impedances of the tapered transmission line circuitry to thereby adjust the impedance match between the source impedance and the load impedance until there is an impedance match between the source impedance and the load impedance.

It may be that the tapered transmission line circuitry includes a tapered transmission line comprising a plurality of discrete sections (e.g. microstrip layers) coupled together.

The method may comprise coupling each of a plurality (or each) of the discrete sections to different tuneable impedance modules. In this case, the method may comprise adjusting the impedances of one or more (or two or more or each) of the said tuneable impedance modules to thereby adjust the impedance match between the source impedance and the load impedance. Preferably, the method comprises coupling each of the said discrete sections to different tuneable impedance modules.

It may be that the method comprises adjusting one or more impedances of the tuneable impedance modules coupled to the discrete sections to thereby improve the impedance match between the source impedance and the load impedance.

It may be that the method comprises providing the tapered transmission line circuitry with first and second tapered transmission lines. It may be that the method comprises (typically symmetrically or asymmetrically) connecting a first tapered transmission line in series with a second tapered transmission line. The method may further comprise coupling a first tuneable impedance module to the first tapered transmission line and coupling a second tuneable impedance module to the second tapered transmission line. The method may further comprise selectively adjusting an impedance (e.g. including a reactance) of the first tapered transmission line module to thereby adjust an impedance match between the source impedance and the load impedance in respect of (e.g. responsive to a determination that) signals propagating between the source impedance and the load impedance having (have) a frequency within a first frequency range. The method may further comprise selectively adjusting an impedance (e.g. including a reactance) of the second tapered transmission line module to thereby adjust an impedance match between the source impedance and the load impedance in respect of (e.g. responsive to a determination that the) signals propagating between the source impedance and the load impedance having (have) a frequency within a second frequency range different from the first frequency range.

It may be that the method comprises determining a frequency of electromagnetic signals propagating from the source impedance to the load impedance. It may be that the method comprises selectively adjusting an impedance of the first tuneable impedance module to thereby adjust the impedance match between the source and load impedances responsive to a determination that the frequency of electromagnetic signals propagating from the source impedance to the load impedance is within the first frequency range and selectively adjusting an impedance of the second tuneable impedance module to thereby adjust the impedance match between the source and load impedances responsive to a determination that the frequency of electromagnetic signals propagating from the source impedance to the load impedance is within the second frequency range.

The method may comprise propagating electromagnetic waves of one or more frequencies within the first frequency range from the source impedance to the load impedance by way of the first tapered transmission line, by-passing the second tapered transmission line. The method may comprise propagating electromagnetic waves of one or more frequencies within the second frequency range from the source impedance to the load impedance by way of the second tapered transmission line, by-passing the first tapered transmission line.

It will be understood that by “impedance match”, we refer to an impedance match for the transfer of maximum (e.g. RF or microwave) signal power from the source impedance to the load impedance. The complex impedance looking towards the load from the source should (ideally) be a complex conjugate impedance of the source (or be equal to the source resistance if the source impedance is purely real). However, it will also be understood that we do not necessarily mean a perfect impedance match, and that the term “impedance match” would also include an approximate impedance match which is within an acceptable range of a perfect impedance match (for the transfer of maximum power). The acceptable range may be selected responsive to one or more user requirements, or to one or more specifications (for example). The acceptable range may be defined with reference to a voltage standing wave ratio (VSWR) at an interface between the source impedance and the load impedance. It may be that the acceptable range comprises a condition specifying that VSWR is less than 3, more typically VSWR is less than 2, in some cases VSWR is less than 1.5, and in some cases VSWR is less than 1.2. It may be that, the more accurate the impedance match required at the interface, the longer it takes to achieve. It may be preferable in some cases to achieve the desired VSWR more quickly at a cost of a less accurate impedance match. In other cases, it may be preferable to achieve a more accurate impedance match at a cost of further delay before the required impedance match is achieved.

Accordingly, by “adjusting” the impedance match between the source impedance and the load impedance, the efficiency of power transfer from the source to the load is thereby adjusted.

By “improving” the impedance match (or providing a “more accurate” impedance match or “reducing an impedance mismatch”) between the source impedance and the load impedance, we refer to adjusting the impedance match to bring it closer to a perfect impedance match for the transfer of maximum power from the source to the load (e.g. to adjust the load impedance as seen by the source (e.g. through the impedance matching circuitry) to bring it closer to the complex conjugate of the source impedance (or closer to the source resistance if the source impedance is purely real)).

The invention also extends to further aspects which relate to a personal electronic mobile (typically portable, typically wireless) communications device comprising the impedance matching circuitry according to the first aspect of the invention or the circuitry according to the second aspect of the invention or comprising computer processing circuitry comprising a computer processor, the computer processing circuitry being configured to perform the method according to the third aspect of the invention.

The invention also extends to a further aspect which relates to a non-transitory computer readable medium retrievably storing computer readable code for adjusting one or more impedances (typically including one or more reactances) of tapered transmission line circuitry coupled between a source impedance and a load impedance to thereby adjust an impedance match between the source impedance and the load impedance.

The preferred and optional features discussed above are preferred and optional features of each aspect of the invention to which they are applicable.

### DESCRIPTION OF THE DRAWINGS

An example embodiment of the present invention will now be illustrated with reference to the following Figures in which:

FIG. 1 shows a tapered transmission line connected in a fixed impedance matching circuit between a source impedance and a load impedance;

FIG. 2 shows a tapered transmission line provided as part of reconfigurable impedance matching circuitry provided between the source impedance and the load impedance;

FIG. 3 shows alternative reconfigurable impedance matching circuitry provided between the source impedance and the load impedance comprising the tapered transmission line of FIG. 2;

FIG. 4 shows an alternative reconfigurable tapered transmission line comprising tuneable impedance circuitry incorporated within the line;

FIG. 5 shows a similar arrangement to FIG. 4, but where the tuneable impedances are implemented in MEMS;

FIG. 6 shows a further alternative reconfigurable tapered transmission line comprising a plurality of tuneable impedances connected in parallel with the line at positions distributed along the length of the line;

FIG. 7 shows two of the tapered transmission lines of FIG. 6 connected back-to-back;

FIGS. 8 and 9 show tapered transmission line arrangements where the tuneable impedance circuitry is connected to the tapered lines through stubs;

FIG. 10A shows tapered transmission line circuitry comprising a plurality of tapered lines, each being designed for a particularly frequency range;

FIG. 10B shows tapered transmission line circuitry comprising a plurality of tapered lines, each being designed for a particularly frequency range, together with bypass circuitry which allows a selected one (or more) of the tapered lines to be connected between the source and the load;

FIG. 11 is a symmetrical tapered transmission line arrangement where the tapered lines of each of two pairs of tapered lines are connected to each other through quarter-wave transformers;

FIG. 12 is a Smith Chart illustrating the Q circle of the arrangement of FIG. 6; and

FIG. 13 is a plot comparing the results of S-parameter analyses on the arrangement of FIG. 6 and on a traditional three stub tuner.

### DETAILED DESCRIPTION OF AN EXAMPLE EMBODIMENT

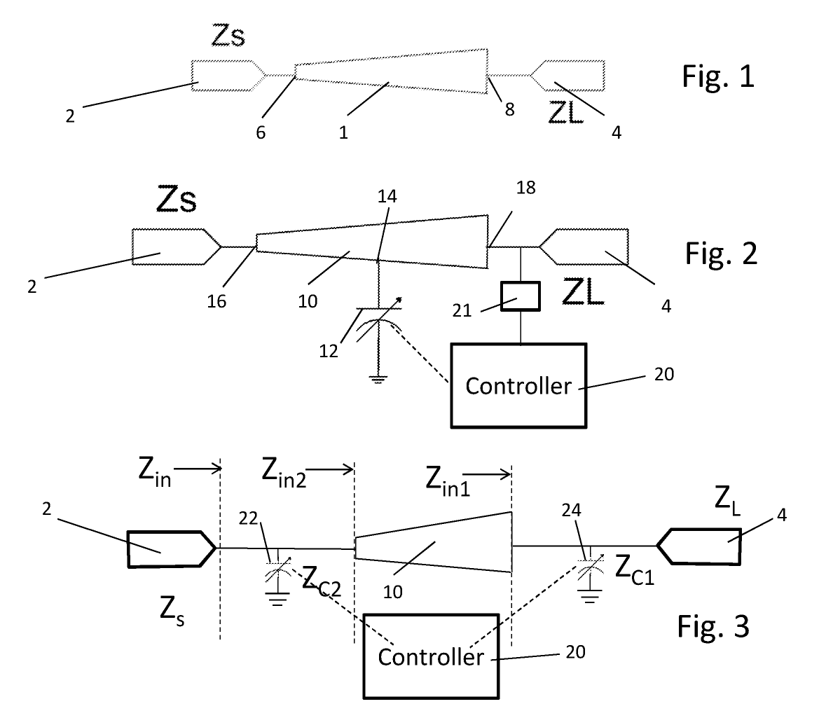

FIG. 1 illustrates a tapered transmission line 1 extending, and configured to provide an impedance match, between a source impedance 2 (Zₛ) and a load impedance 4 (Z_{L}). The tapered transmission line 1 is provided on a substrate which is itself mounted on a ground plane. The tapered transmission line 1 has a characteristic impedance Z_{Taper} which varies along its length in accordance with the following function:

$$ZTaper = \frac{60}{\sqrt{ɛ r ( z )}} ln [ \frac{8 d}{W ( z )} + \frac{W ( z )}{4 d} ] ; \frac{W ( z )}{d} \leq 1$$

$$ZTaper = \frac{120 π}{\sqrt{ɛ r ( z )} [ \frac{W ( z )}{d} + 1.393 + 0.667 ln ( \frac{W ( z )}{d} + 1.444 ) ]} ;$$

$$\frac{W ( z )}{d} > 1$$

where:
Z_{Taper} is the characteristic impedance of the tapered transmission line;
W(z) is the width of the tapered transmission line which is a function of position z along the length of the tapered transmission line 1 from a first end 6 connected to the source impedance 2 and a second end 8 connected to the load impedance 4;
d is the thickness of the substrate;
εᵣ (z) is the effective permittivity of the tapered transmission line, which varies with position along the taper as follows:

$${ɛ}_{r} ( z ) = \frac{{ɛ}_{s} + 1}{2} + \frac{{ɛ}_{s} - 1}{2} \frac{1}{\sqrt{1 + 12 d / W ( z )}}$$

where: ε_{S} is the relative permittivity of the substrate.

The effective permittivity of the tapered transmission line 1 varies continuously along its length due to the continuously varying width of the line 1. The varying effective permittivity along the transmission line 1 influences the characteristic impedance of the tapered transmission line 1 such that the tapered transmission line also has a continuously varying characteristic impedance along its length. In order to optimise the (real) impedance match between the source impedance 2 and the tapered transmission line 1, the first end 6 of the tapered transmission line 1 has a characteristic impedance Z_{Taper}=Zₛ. In addition, in order to optimise the (real) impedance match between the second end 8 and the load impedance 4, the second end 8 of the tapered transmission line 1 has a characteristic impedance Z_{Taper}=Z_{L}. In order to optimise the impedance match between the source 2 and the load 4, the characteristic impedance of the tapered transmission line 1 should vary gradually between Z_{S} and Z_{L}.

For example, it may be that the characteristic impedance Z_{Taper} of the tapered transmission line 1 varies in accordance with the following exponential function:

Z_{Taper}=Z_{S}e^{az}

where: Z_{source} is the source impedance;

a=(1/l)ln(Z_{L}/Zₛ);

where: l is the physical length of the tapered transmission line from the first end 6 to the second end 8.

As required, at the first end 6 of the tapered transmission line, where z=0, the characteristic impedance Z_{Taper} of the tapered transmission line is equal to Zₛ. At the second end 8 of the tapered transmission line, where z=L, the characteristic impedance Z_{Taper} of the tapered transmission line is Z_{L}.

The effective permittivity εᵣ (z), phase velocity vₚ and characteristic impedance Z_{Taper} of the tapered transmission line 1 are also functions of the frequency of electromagnetic waves propagating along the line 1. The tapered transmission line has a broadband, high-pass frequency response, the lower cut-off frequency being determined by the electrical length of the tapered transmission line. For the propagation of electromagnetic waves having wavelength λ between the source 2 and the load 4 by way of the tapered transmission line 1, the electrical length of the tapered transmission 1 line should be at least 0.5λ.

Although the tapered transmission line 1 is typically considered to have an impedance which varies continuously along its length, it is typically formed from the combination of a plurality of discrete (e.g. microstrip) sections coupled together, the discrete sections being small enough that the impedance of the tapered transmission line can be considered to increase or decrease continuously along its length (e.g. each of the discrete sections having an electrical length which is less than a quarter of the wavelength of electromagnetic waves propagating on the tapered transmission line from the source 2 to the load 4). Typically the discrete sections are not tapered themselves (each section is typically provided with a constant width along its length), but rather the width of subsequent sections along the line varies to provide the tapered transmission line with its taper. In order to optimise the impedance match between the source 2 and the load 4, the impedance of the transmission line varies gradually along its length (as stated above), typically by providing subsequent sections along the length of the line with widths which vary by a small amount from the preceding section. In addition, each section of the tapered transmission line is provided with the same electrical length.

The electrical length of a particular section of the tapered transmission line 1 is typically expressed as a fraction of a wavelength λₛ of electromagnetic waves propagating on that section of the tapered transmission line 1:

λ_{S}=vₚ/(f√εᵣ(z))

where
vₚ is the phase velocity of electromagnetic waves of frequency f propagating along that section of the tapered transmission line 1;
f is the frequency of electromagnetic waves of wavelength λ propagating along the tapered transmission line; and
εᵣ(z) is the effective permittivity of the tapered transmission line (see above).

It may be that the effective permittivity of each discrete section of the tapered transmission line is constant along its length, the effective permittivity of subsequent sections along the length of the tapered transmission line varying by a small amount from the preceding section.

Each section of the tapered transmission line can be provided with the same electrical length by providing each section with a different physical length, taking into account the ratio of width of the tapered transmission line for that section (which typically has constant width) to the substrate thickness of that section (the ratio of the width of the tapered transmission line for that section to the thickness of the substrate at that section being equivalent to the phase velocity).

Electrical length is proportional to phase velocity. The phase velocity vₚ is subject to the relative permittivity εᵣ (z) of the tapered transmission line 1, and is therefore also a function of position along the tapered transmission line 1.

The tapered transmission line may be modelled by a lump inductance, L, and a lumped capacitance, C, and the values of the lumped inductance L and the lumped capacitance C as a function of the characteristic impedance of the tapered transmission line 1 can be calculated as follows:

Inductance, L=(Z_{Taper}(z)/(2πf))sin(2πl/λₛ)

Capacitance, C=(1/(2πfZ_{Taper}(z)))tan(πl/λₛ)

where:
Z_{Taper} (z) is the characteristic impedance of the tapered transmission line as a function of position z along the tapered transmission line;
f is the frequency of electromagnetic signals propagating on the tapered transmission line;
l is the physical length of the tapered transmission line; and
λₛ is the wavelength of electromagnetic waves propagating on the section, s, of the tapered transmission line provided at position z along the length of the tapered transmission line.

The phase velocity vₚ of a transmission line can be written as:

vₚ=1/√LC

where:
L is the lump inductance of the tapered transmission line (see above);
C is the lump capacitance of the tapered transmission line (see above).

As the lump capacitances and inductances change along the length of the tapered transmission line (in order to provide the tapered transmission line with its gradually varying impedance), the phase velocity vₚ also changes. Indeed, as the impedance of the tapered transmission line must vary gradually along its length between its first and second ends, the phase velocity vₚ must also vary gradually along the length of the tapered transmission line. In order to design the tapered transmission line such that the electrical lengths of each discrete section are equal to each other, an average (constant) phase velocity vₚ is used for the design of each section. For example, for each section of the tapered transmission line, the (average) phase velocity may be calculated as the mean of the required phase velocities at first and second ends of that section (it being understood that the first and second ends are spaced from each other along the direction of electromagnetic signal propagation along the tapered transmission line).

Tapered transmission lines such as the one shown in FIG. 1 are typically used in (fixed) impedance matching networks to match a fixed real source impedance Z_{S} with a fixed real load impedance Z_{L} over a range of frequencies. If one or both of the source impedance Z_{S} and the load impedance Z_{L} comprises a frequency dependent impedance, an impedance mismatch would be observed between the frequency dependent impedance of the source/load and the tapered transmission line 1.

It may be that the source comprising the source impedance 2 comprises an RF front end of a wireless communications device (such as a smartphone, tablet, phablet or wearable device) and the load comprising the load impedance 4 comprises an antenna (or an antenna module comprising one or more antennae) of that device. It may be that the antenna is provided as part of the casing of the wireless communications device, in which case interaction (or changes in the interaction) between the user and the casing, such as the user holding the case in a certain way in his/her hands, can cause the RF front end to see a reactance in the antenna load. This causes electromagnetic waves propagating along the tapered transmission line to see a reactance at the load (rather than a purely resistive impedance), which in turn leads to increased signal reflections at the circuit interface, and reduced power transfer, between the tapered transmission line 1 and the load 4.

Furthermore, changes in the frequency of signals transmitted and received by the wireless communications device lead to changes in frequency dependent impedances at the source 2, the load 4 and along the tapered transmission line 1 which also affects the impedance match between the source 2 and the load 4.

FIG. 2 illustrates tapered transmission line circuitry comprising a (asymmetrical) tapered transmission line 10 similar to the line 1 shown in FIG. 1 (indeed the tapered transmission line 10 having the properties of tapered transmission line 1 unless otherwise stated), and again extending between the source 2 and the load 4, and tuneable impedance circuitry 12. The tuneable impedance circuitry 12 is provided in communication with a controller 20 (which may be a processor, digital signal processor or microcontroller, for example) configured to control the impedance (typically including the reactance) thereof by way of current and/or voltage control signals. The tuneable impedance circuitry (typically comprising one or more tuneable reactive components comprising a tuneable reactance, in this case a tuneable capacitor) 12 is connected between an intermediate position 14 along the length of the tapered transmission line 10 (between a first end 16 connected to the source 2 and a second end 18 connected to the load 4) and ground.

It will be understood that if the output impedance of the source 2 and the input impedance of the load 4 are complex, then it is preferable (in order to maximise power transfer from the source 2 to the load 4) for the input impedance of the tapered transmission line 10 (as seen by the source) to be equal to the complex conjugate of the source impedance and for the output impedance of the tapered transmission line 10 (as seen by the load) to be equal to the complex conjugate of the load impedance. In the event that there is an (e.g. complex) impedance mismatch between the source 2 and the load 4, the controller 20 is configured to adjust the impedance (typically including the reactance) of the tuneable impedance circuitry 12 in order to bring the input impedance of the tapered transmission line circuitry closer to (preferably to equal) the complex conjugate of the source impedance 2 and/or to bring the output impedance of the tapered transmission line circuitry closer to (preferably to equal) the complex conjugate of the load impedance 4 (as necessary).

The tuneable impedance circuitry 12 (or indeed the tuneable impedance circuitry or any of the tuneable impedance modules of all other examples discussed herein) may comprise one or more (active or reactive) components or one or more groups of components having an impedance (typically including a reactance) which can be current or voltage controlled. For example, the tuneable impedance circuitry 12 may comprise a bank of switched (e.g. MEMS) capacitors (which may each have fixed or individually tuneable capacitances) having an impedance which can be current or voltage controlled (e.g. by selectively opening or closing capacitor switches to activate or deactivate capacitors within the bank, thereby controlling which capacitors are connected in parallel with each other, thereby controlling the impedance of the bank as a whole). Additionally or alternatively, the tuneable impedance circuitry may comprise one or more components having tuneable inductances or capacitances, or ohmic switches or couplings capable of compensating an impedance mismatch between the source 2 and the load 4 by varying capacitance, inductance, impedance and/or magnetic flux. The tuneable components may comprise, for example, semiconductor varactors, MEMS varactors, MEMS switched capacitors, ferroelectric capacitors, a bank of switched capacitors (e.g. a bank of switched MEMS capacitors), P-I-N diode or any other component capable of implementing an impedance (typically including a reactance) which is tuneable responsive to a control signal. Preferably the tuneable capacitances comprise MEMS switched capacitors (e.g. a bank thereof) having capacitances which tune linearly responsive to a linearly varying (e.g. voltage and/or current) control signal. In a particular example, the tuneable capacitances comprise a bank of switched MEMS tuneable capacitors. In this case, the capacitance of each of the capacitors can be changed by way of voltage and/or current control signals provided by the controller 20 to the capacitors, and the capacitance of the bank as a whole can be further controlled by selecting the number of tuneable MEMS capacitors connected in parallel by activating and deactivating their respective switches as required.

An impedance mismatch sensor 21 is also provided in communication with the source and/or load impedances 2, 4 and which is configured to detect an impedance mismatch between the source impedance 2 and the load impedance 4 (e.g. to detect that the output impedance of the source 2 does not match the input impedance of the load 4, and/or to detect that the output impedance of the source 2 does not match the input impedance of the tapered transmission line circuitry, and/or to detect that the output impedance of the tapered transmission line circuitry does not match the input impedance of the source). The impedance mismatch sensor may for example comprise one or more of the following: RF voltage detector (such as a diode detector, temperature compensated diode detector, logarithmic amplifier or any other means to detect an RF voltage magnitude), phase detector (such as one or more variable capacitor or any other means to detect an RF phase magnitude) or power detector (such as one or more directional coupler or any other means to detect an RF power). The impedance mismatch sensor 21 is typically provided in communication with the controller 20, and the controller 20 is configured to adjust the impedance of the tuneable impedance circuitry 12 responsive to the detection of an impedance mismatch between the source 2 and the load 4 by the impedance mismatch sensor 21. The impedance (e.g. including a reactance) of the tuneable impedance circuitry 12 is iteratively adjusted by the controller 20 until an acceptable impedance match between the source 2 and the load 4 is achieved.

As the tapered transmission line 10 has a broadband frequency response, the same tapered transmission line 10 can be used in a reconfigurable impedance matching network between the source 2 and the load 4 over a wide range of electromagnetic frequencies. The fact that the same tapered transmission line can be used to perform impedance matching over a wide range of frequencies significantly reduces impedance states (an impedance state consists of a set of potential impedance values, for example pre-calculated from an antenna feed point, for each particular frequency band to correct an impedance mismatch), converging/reconfiguration time (due to the reduced number of impedance states) and the quantity of initialisation data that needs to be calculated by the impedance matching circuitry (as compared to providing several narrow-band impedance matching networks) because one impedance state can be used for many operating frequencies.

It may be that the controller 20 is provided in communication with a memory storing a look-up table which associates each of a plurality of impedance configurations with one or more conditions such as one or more impedance mismatch conditions (detectable by the impedance mismatch sensor 21) and/or one or more frequency conditions. It may be that the controller 20 is configured to determine the frequency of electromagnetic signals propagating along the tapered transmission line 10, to select one or more impedance configuration associated with that frequency from the look-up table, and to configure the tuneable impedance circuitry 12 in accordance with the selected impedance configuration, for example prior to the iterative process being performed. Each of the configuration data in the look-up table typically provides at least an approximate impedance match between the source 2 and the load 4 at the frequency associated with that data (optionally in response to a particular mismatch condition). The impedance (e.g. including a reactance) of the tuneable impedance circuitry 12 may then if necessary be fine-tuned (i.e. iteratively adjusted) by the controller 20 until an acceptable impedance match between the source 2 and the load 4 is achieved (e.g. until an acceptable impedance match is detected by the impedance mismatch sensor 21). The configuration data in the look-up table reduces the number of iterations required to obtain an acceptable impedance match.

The frequency of electromagnetic signals propagating along the transmission line may be provided as an input to the controller 20, thereby enabling the controller 20 to select the correct configuration from the look-up table. For example, if the reconfigurable impedance matching circuitry was implemented on a wireless communications device between an RF front end and an antenna module, it may be that the frequency of electromagnetic signals propagating along the transmission line 10 is provided to the controller 20 by baseband circuitry of the wireless communications device. Additionally or alternatively an impedance mismatch condition detected by the impedance mismatch sensor 21 may be provided as an input to the controller 20, thereby enabling the controller 20 to select the correct configuration from the look-up table.

FIG. 3 shows alternative impedance matching circuitry provided between the source 2 and the load 4 comprising a tapered transmission line 10, a first bank of switched MEMS tuneable capacitors 22 connected between the first (higher impedance, narrower) end of the tapered transmission line 10 and ground and a second bank of switched MEMS tuneable capacitors 24 connected between the second (lower impedance, wider) end of the tapered transmission line 10 and ground, the said bands of switched MEMS tuneable capacitors having tuneable capacitances Z_{C2} and Z_{C1} respectively. Three input impedance values, Zᵢₙ, Zᵢₙ₁ and Zᵢₙ₂ can be considered in the example of FIG. 3, being the input impedance of the combination of the impedance matching circuitry 22, 10, 24 and the load 4 as seen by the source, Zᵢₙ₂ being the input impedance of the combination of the tapered transmission line 10, the second bank of switched capacitors 24 connected to the second (lower impedance, wider) end of the tapered transmission line 10 and the load 4 as seen from the first (higher impedance, narrower) end of the tapered transmission line 10, and Zᵢₙ₁ being the input impedance of the combination of the second bank of switched capacitors 24 and the load 4 as seen by the second (lower impedance, wider) end of tapered transmission line 10. These impedances can be calculated as follows:

Zᵢₙ₁=Z_{C1}//Z_{L},

where Z_{C1}=1/2πfC₁ and C₁ is the capacitance from the second bank of tuneable capacitors 24.

$${Z}_{in 2} = {Z}_{Taper} ( z ) * \frac{( {Z}_{in 1} + {jZ}_{Taper} ( z ) tan β t )}{( {Z}_{Taper} ( z ) + {jZ}_{in 1} tan β t )}$$

where
β is a propagation constant of the tapered transmission line 10,
t is the physical length of the tapered transmission line 10 and
Z_{Taper} (z) is the characteristic impedance of the tapered transmission line 10.

Z_{Taper} is a function of position along the line. To calculate Zᵢₙ₂, the impedance of the tapered transmission line at the first end of the tapered transmission line (Z_{Taper}(0)) is used. If the tuneable impedance matching circuitry was connected to the tapered transmission line at an intermediate position along its length, the value of Zₜₐₚₑᵣ at that position would be used instead.

Zᵢₙ=Zᵢₙ₂//Z_{C2}

where Z_{C2}=1//2πfC2 and C2 is the capacitance from the first bank of tuneable capacitors 22.

To obtain an impedance match between Zₛ and Z_{L}, individual impedance matches between the following pairs of impedances are sought:

$${Z}_{S} with {Z}_{IN} , \\ {Z}_{IN 2} with {Z}_{s} \text{//} {Z}_{C 2} , \\ {Z}_{IN 1} with {Z}_{Taper} ( z ) * \frac{( ( {Z}_{s} \text{//} {Z}_{C 2} ) + {jZ}_{Taper} ( z ) tan β t )}{( {Z}_{Taper} ( z ) + j ( {Z}_{s} \text{//} {Z}_{C 2} ) tan β t )} and$$

$${Z}_{L} with {Z}_{C 1} \text{//} {Z}_{Taper} ( z ) * \frac{( ( {Z}_{s} \text{//} {Z}_{C 2} ) + {jZ}_{Taper} ( z ) tan β t )}{( {Z}_{Taper} ( z ) + j ( {Z}_{s} \text{//} {Z}_{C 2} ) tan β t )}$$

where Z_{Taper} (z) is the impedance of the tapered transmission line 10 at the wider, low impedance end of the tapered transmission line 10 (i.e. the end closest to the load)

When an impedance mismatch is detected by the impedance mismatch sensor 21, these equations can be solved for values of C1 and C2 which provide an impedance match (or at least improve the impedance match) between Zₛ and Z_{L}, which are stored in the look-up table and associated with impedance mismatch values obtained from the impedance mismatch sensor 21. The values of C1 and C2 are also set to the solved values to improve the impedance match between Zₛ and Z_{L}. When the mismatch sensor later detects the same or a similar mismatch, the values of C1 and C2 can be obtained from the lookup table without having to recalculate them. As discussed above, the values of C1 and C2 can be iteratively adjusted (fine-tuned) if necessary in order to obtain a suitable impedance match.

As will now be described, the tapered transmission line 10 and tuneable impedance circuitry 12 of FIG. 2 (or tuneable impedance circuitry 22, 24 in the case of FIG. 3) may be replaced by one of a number of alternative reconfigurable tapered transmission line arrangements. Each of the arrangements discussed below comprise tapered transmission line circuitry comprising one or more tapered transmission lines extending between the source 2 and the load 4, and typically also tuneable impedance circuitry configured to adjust the impedance of the tapered transmission line circuitry to thereby obtain an impedance match between the source 2 and the load 4. The impedance matching sensor 21 is not shown in FIGS. 3-11 but it will be understood that it is typically provided and configured as discussed above in relation to FIG. 2.

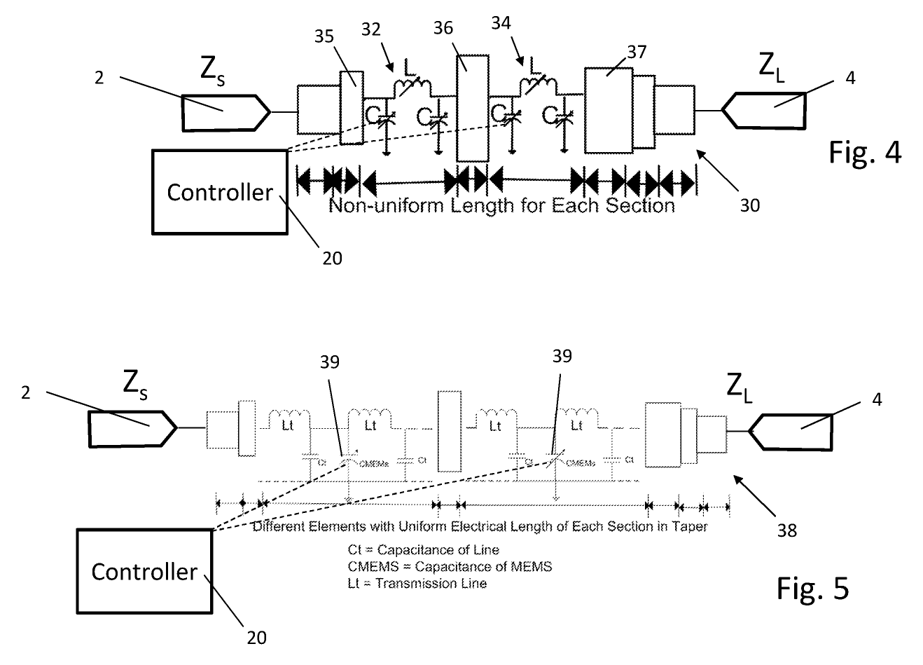

FIG. 4 shows alternative tapered transmission line circuitry comprising a tapered transmission line 30 connected between the source 2 and the load 4 and first and second tuneable impedance modules 32, 34 incorporated within the tapered transmission line 30 in an asymmetrical arrangement. The tapered transmission line 30 is formed from a plurality of discrete sections of non-uniform physical lengths (but uniform electrical lengths). The first tuneable impedance module 32 is provided between two adjacent (discrete) sections 35, 36 of the tapered transmission line 30 at an intermediate position along its length closer to the source impedance 2 than to the load impedance 4, and the second tuneable impedance module 34 is provided at an intermediate position along its length closer to the load impedance 4 than to the source impedance 2 between adjacent (discrete) sections 36 and 37 of the tapered transmission line 30. The length of the tapered transmission line 30 between the source impedance 2 and the first tuneable impedance module 32 is less than the length of the tapered transmission line 30 between the second tuneable impedance module 34 and the load impedance 4. It is noted for completeness that although significant steps are shown between adjacent discrete sections of the transmission line 30 in FIG. 4, the steps are typically less pronounced in practice (indeed the taper may be continuous along the length of the transmission line 30).

The first and second tuneable impedance modules 32, 34 are each provided in communication with the controller 20, and each comprise a tuneable inductance L connected in series between adjacent sections of the tapered transmission line 30 and a pair of tuneable capacitances C connected in parallel with the said adjacent sections of the tapered transmission line 30 (and to ground). The inductances of the tuneable inductances L and the capacitances of the tuneable capacitances C can be adjusted by the controller 20 to improve the impedance match between the source 2/load 4 and the tapered transmission line 30.

Typically the tuneable inductances L and the tuneable capacitances C are implemented in MEMS so as to allow the physical size of the tapered transmission line 30 to be kept low. This is illustrated by the asymmetrical tapered transmission line 38 shown in FIG. 5, which comprises a plurality of tuneable MEMS capacitances 39 (which may comprise one or more tuneable MEMS capacitors or, more typically, a bank of MEMS capacitors (which may or may not be individually tuneable) having an impedance (capacitance) which can be current or voltage controlled, for example by selectively opening or closing capacitor switches to activate or deactivate capacitors within the bank) connected to the tapered transmission line 38 at intermediate positions distributed along the length of the tapered transmission line 38. FIG. 5 also explicitly illustrates the distributed capacitances and inductances Cₜ, Lₜ of the transmission line 38 along its length.

By providing the tapered transmission line circuitry with tuneable impedance modules having connections to a tapered transmission line distributed along the lengths of the tapered transmission line 30, 38 (rather than at only one point on the tapered transmission line), more flexibility is obtained as to the way in which the tuneable impedance circuitry 32, 34, 39 can be configured to bring the input impedance of the tapered transmission line circuitry closer to the complex conjugate of the source impedance 2 and/or to bring the output impedance of the tapered transmission line circuitry closer to the complex conjugate of the load impedance 4 (as required). The fact that the tuneable impedance modules 32, 34, 39 are incorporated within the tapered transmission lines 30, 38 also reduces the additional footprint that would otherwise be required by the addition of the tuneable impedance modules to the impedance matching circuitry.

It will be understood that any number of tuneable MEMS capacitors could be provided in the arrangement of FIG. 5, typically distributed along the length of the tapered transmission line 38. For example, one tuneable MEMS capacitor may be provided per section of the tapered transmission line.

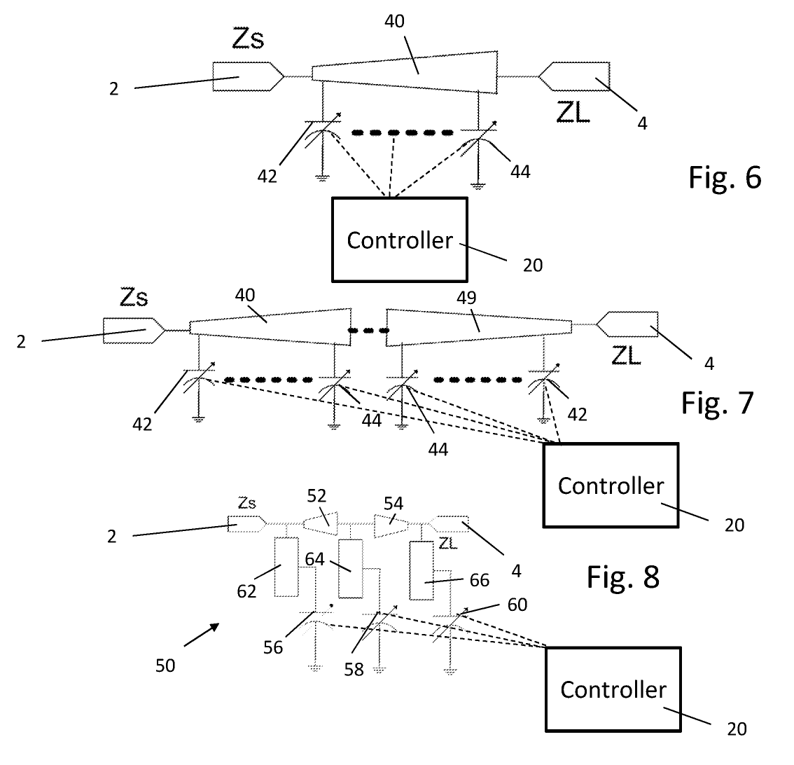

FIG. 6 shows further alternative (asymmetrical) tapered transmission line circuitry comprising a tapered transmission line 40 connected between the source 2 and the load 4. The tapered transmission line 40 is similar to the tapered transmission line 10 shown in FIG. 2, but rather than having a single tuneable impedance module 12 connected at an intermediate position along its length, a plurality of tuneable impedance modules 42, 44 are connected to the tapered transmission line 40 at various positions distributed along its length between its greater impedance end and its lower impedance end (the tuneable impedance modules 42, 44 being connected between the tapered transmission line 40 and ground). It will be understood that although only two tuneable impedance modules 42, 44 are shown, the dotted lines between impedances 42, 44 are indicative that any number of tuneable impedance modules may be connected to the tapered transmission line 40 along its length. As above, distributing tuneable impedance modules along the length of the tapered transmission line 40 provides more flexibility as to the way in which the tuneable impedance circuitry can be configured to obtain an impedance match between the source 2 and the load 4. Again, the tuneable impedance modules 42, 44 can be implemented using any of the ways discussed above (or indeed any other suitable way), and the tuneable impedance modules 42, 44 are provided in communication with, and under the control of, the controller 20.

FIG. 7 shows the tapered transmission line 40 connected in series in a symmetrical back-to-back configuration (i.e. the wider end of the tapered transmission line 40 is connected to the wider end of the tapered transmission line 49) with an identical tapered transmission line 49. This arrangement is particularly useful if, for example, the source 2 is required to be interfaced with other (e.g. off-the-shelf) components or network analysers if for example the size of the tapered transmission line 40 at one end (e.g. the wider end) is unsuitable for interfacing with existing equipment. By connecting the transmission line 49 in series with the transmission line 40 in a back-to-back arrangement, the size (width) of the (e.g. narrower) end of the tapered transmission line 49 can be matched to the size required by existing equipment. Each of the tapered transmission lines 40, 49 have tuneable impedance modules 42, 44 connected thereto at positions distributed along their lengths. However, in other arrangements it may be that each of the tapered transmission lines 40, 49 have a single tuneable impedance module connected to an intermediate portion thereof along their lengths or one or more tuneable impedance modules may be integrated within the tapered transmission lines 40, 49. As before, the tuneable impedance modules 42, 44 are typically provided in communication with, and their impedances are controlled by, the controller 20.

It will be understood that, although only two tapered transmission lines 40, 49 are shown in the arrangement of FIG. 7, the dotted lines between transmission lines 40, 49 indicate that any number of tapered transmission lines may be provided between transmission lines 40, 49. Typically, adjacent pairs of transmission lines are connected front to front or back to back. Furthermore, the dotted lines between tunable impedances 42, 44 are indicative that any number of tunable impedances may be connected to the tapered transmission lines along their lengths.

FIG. 8 illustrates further alternative (symmetrical) tapered transmission line circuitry 50 comprising a pair of tapered transmission lines 52, 54 connected in series in a back-to-back configuration between the source 2 and the load 4. Three tuneable capacitances 56, 58, 60 are provided: a first tuneable capacitance 56 connected to an intermediate portion along the length of a first stub 62 (between two opposing ends thereof) connected at a point between the source 2 and the first tapered transmission line 52; a second tuneable capacitance 58 connected to an intermediate portion along the length of a second stub 64 (between two opposing ends thereof) connected at a point between the two tapered transmission lines 52, 54; and a third tuneable capacitance 60 connected to an intermediate portion along the length of a third stub 66 (between two opposing ends thereof) connected at a point between the second tapered transmission line 54 and the load 4. By connecting the tuneable capacitances 56, 58, 60 to the tapered transmission lines indirectly by way of the respective stubs 62, 64, 66, the frequency range of reconfiguration of the impedances 56, 58, 60 is extended because the respective stubs 62, 64, 66 provide additional reactance to the impedance matching circuitry.

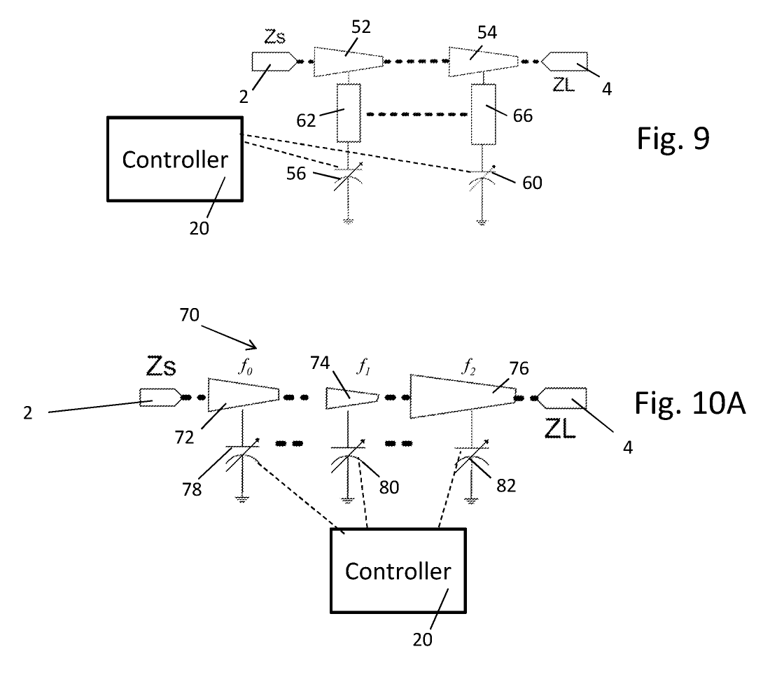

As illustrated in the asymmetrical tapered transmission line circuitry of FIG. 9, the tuneable impedance modules 56-60 (impedance 58 not shown) may alternatively be connected to an end (e.g. the opposite end of the stub to that connected to the respective tapered transmission line) of the respective stub 62-66 (stub 64 not shown). In addition, the tapered transmission lines are not necessarily connected back-to-back. In FIG. 9, adjacent tapered transmission lines are connected in series front-to-back (i.e. the narrower end of the tapered transmission line is connected to the wider end of an adjacent tapered transmission line). It will also be understood that any number of tapered transmission lines may be connected to each other, and any number of corresponding stub/tuneable impedance module combinations may also be provided. It will also be understood that (as also shown in FIG. 9) the stubs 62-66 may be connected directly to the tapered transmission lines (e.g. at intermediate positions along their length) rather than to the ends thereof as illustrated in FIG. 8.

As above, the impedances of tuneable impedance modules 56-60 can be tuned by the controller 20 (e.g. responsive to detection of an impedance mismatch by the impedance mismatch sensor 21) to obtain an acceptable impedance match between the source 2 and the load 4.

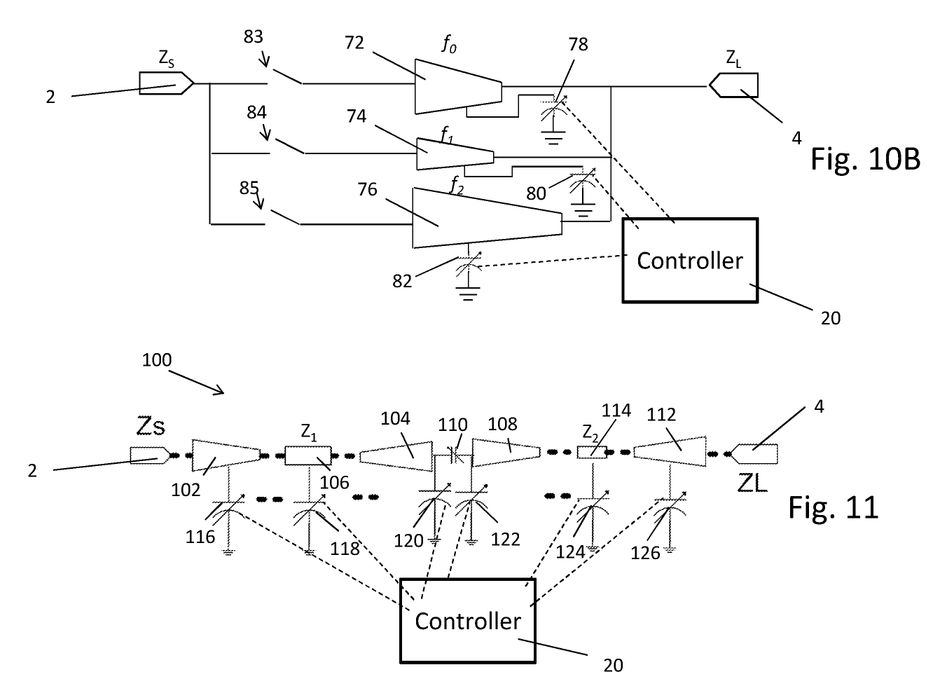

As shown in FIG. 10A, further alternative asymmetrical tapered transmission line circuitry 70 is provided. In this case, a plurality of tapered transmission lines 72, 74, 76 is provided between the source 2 and the load 4, each of the tapered transmission lines 72, 74, 76 having different taper structures, each being suitable for use over different frequency ranges (tapered transmission line 72 being suitable for impedance matching at operating frequencies within a first frequency range f₀, tapered transmission line 74 being suitable for impedance matching at operating frequencies within a second frequency range f₁, and tapered transmission line 76 being suitable for impedance matching at operating frequencies within a third frequency range f₂, where f₀>f₁>f₂). Typically (e.g. at least one or both ends of) the tapered transmission lines 72, 74, 76 are of different sizes (and/or have different substrate permittivity profiles) to provide different impedance profiles for given frequencies (or a given impedance profile for different operating frequencies or frequency ranges). In this case, the tapered transmission line circuitry comprises (different) respective tuneable impedance modules 78, 80, 82, each being connected to a respective tapered transmission line 72, 74, 76 (in this example, at an intermediate position along the length of the tapered transmission line 72, 74, 76). The respective tuneable impedance modules 78, 80, 82 may be tuned across a range of impedances specifically designed for the frequency range associated with the tapered transmission line to which it is connected.

It may be that the tapered transmission lines 72, 74, 76 are fixedly connected in series with each other between the source 2 and the load 4, in which case for each frequency range f₀, f₁, f₂, the electromagnetic signals propagating between the source 2 and the load 4 are required to propagate along each of the tapered transmission lines 72, 74, 76. In this case, the frequency responses of the tapered transmission lines 72, 74, 76 should be designed to allow signals of each frequency f₀, f₁, f₂ to propagate along them substantially unattenuated. The tuneable impedance module(s) connected to the tapered transmission line 72-76 associated with the frequency range containing the frequency of electromagnetic signals propagating on the line is tuned to achieve the impedance match between the source 2 and the load 4.

Alternatively, by-pass circuitry may be provided so that: signals of frequency in the first range f₀ propagate along the first tapered transmission line 72 and by-pass the second and third tapered transmission lines 74, 76; signals of frequency f₁ propagate along the second tapered transmission line 74 and by-pass the first and third tapered transmission lines 72, 76; and that signals of frequency f₂ propagate along the third tapered transmission line 76 and by-pass the first and second tapered transmission lines 72, 74. This is illustrated in FIG. 10B which shows the transmission lines 72-76 arranged in parallel with each other, with respective switches 83-85 being provided between the source 2 and the respective transmission lines 72-76 for selectively coupling one or more of the transmission lines 72-76 between the source 2 and the load 4. It will be understood that the controller 20 is in communication with the switches, such that the controller 20 can cause the switches to open or close depending on which transmission line 72-76 (or transmission lines 72-76) is (are) to be connected between the source and the load.

A similar arrangement (which may even omit the tuneable impedance modules 78-82) can also be used to adjust the impedance match between the source 2 and the load 4 at a single operating frequency (or range of operating frequencies), whereby a different transmission line 72-76 (or a different combination of transmission lines) is selectively coupled between the source 2 and the load 4 in order to achieve an impedance match between the source 2 and the load 4.

Although in some circumstances it is beneficial to have a plurality of different tapered transmission lines, each covering a different frequency band, it will be understood that because each tapered transmission line has a broadband response, far fewer tapered transmission lines are required to cover a given frequency range than more traditional reconfigurable narrow-band impedance matching circuits. Accordingly, the number of searching states required and the convergence/reconfiguration time is still reduced significantly.

Although only three tapered transmission lines (and therefore three frequency ranges) are considered here, it will be understood that any number of tapered transmission lines may be provided (with corresponding tunable impedances).

FIG. 11 shows yet further alternative (symmetrical) tapered transmission line circuitry 100 comprising first and second tapered transmission lines 102, 104 connected serially front to front (the narrower ends of the tapered transmission lines being connected to each other) through a first quarter wave transformer 106. The second tapered transmission line 104 is connected serially back to back with a third tapered transmission line 108 by way of a tuneable capacitance 110. The third tapered transmission line 108 is connected serially front to front to a fourth tapered transmission line 112 through a second quarter wave transformer 114. The tuneable impedance circuitry in this case comprises the tuneable capacitance 110, and additional tuneable capacitances 116 (connected between an intermediate position along the length of the first tapered transmission line 102 and ground), 118 (connected between an intermediate position along the length of the first quarter wave transformer 106 and ground), 120 (connected between the back end of the second tapered transmission line 104 and ground), 122 (connected between the back end of the third tapered transmission line 108 and ground), 124 (connected between an intermediate position along the length of the second quarter wave transformer 114 and ground) and 126 (connected between an intermediate position along the length of the fourth tapered transmission line 112 and ground). The quarter wave transformers 106, 112 (in combination with the tuneable capacitances 118, 124) provide additional flexibility because they are able to assist (typically only) with the correction of the real part of an impedance mismatch between the source 2 and the load 4. The quarter wave transformers 106, 112 (in combination with the tuneable capacitances 118, 124) help to provide an impedance match between the tapered transmission lines between which they are provided. That is, quarter wave transformer 106 helps to provide an impedance match between tapered transmission lines 102, 104 and quarter wave transformer 114 helps to provide an impedance match between tapered transmission lines 108, 112.

It will again be understood that any suitable number of tapered transmission lines, quarter wave transformers, tuneable impedances etc may be provided in the arrangement of FIG. 11 between the source 2 and the second tapered transmission line 104, and between the third tapered transmission line 108 and the load 4.

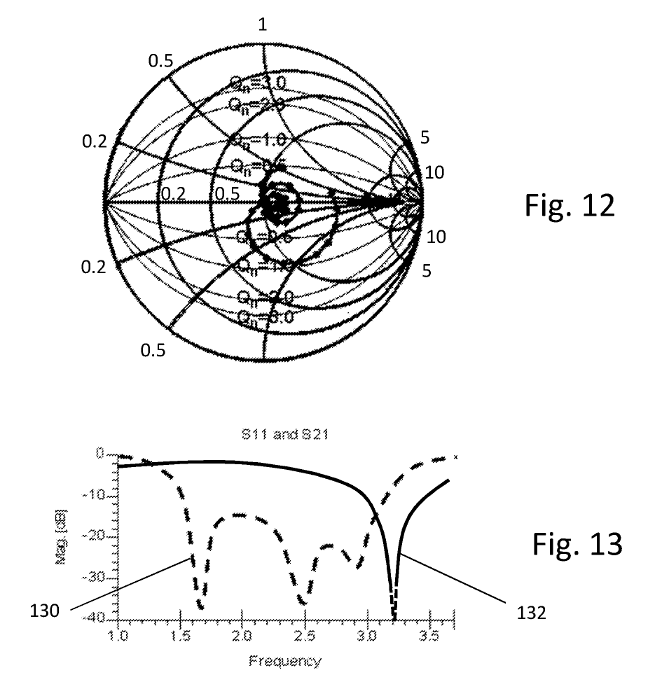

FIG. 12 illustrates the impedance points of the reconfigurable tapered transmission line circuitry shown in FIG. 6 on a Smith chart. It can be seen that a low Q circle is provided, which is indicative of a wide bandwidth for impedance matching. This is further illustrated in FIG. 13 which shows the results 130 of an S-parameter analysis of the reconfigurable tapered transmission line 40 shown in FIG. 6, versus the results 132 of an S-parameter analysis of a 3 stubs tuner. It can be seen that a significantly wider bandwidth is provided by the reconfigurable tapered transmission line circuitry than the three stubs tuner.

Further variations and modifications may be made within the scope of the invention herein described.

For example, the tapered transmission lines discussed above, although discussed in terms of a tapering width, can additionally or alternatively be implemented by varying the thickness (distance between the upper surface of the tapered transmission line and the substrate) of the transmission line and/or by varying the permittivity of substrate underneath transmission line.

In addition, although many of the examples of tuneable impedance circuitry/modules discussed are referred to as tuneable capacitances, it will be understood that any suitable tuneable impedance circuitry/modules could be used instead (e.g. any series and/or parallel combination of resistances, capacitances, inductances or devices which vary magnetic flux may be employed). The tuneable impedance circuitry/modules may comprise tuneable reactive components having, for example, inductances or capacitances which are tuneable and/or groups of components having impedances which are tuneable as a whole (e.g. banks of MEMS capacitors as discussed above).

Tuneable impedance circuitry may be connected to the tapered transmission lines in series or in parallel, and tuneable impedance circuitry may be connected to the tapered transmission lines directly or indirectly.

It will also be understood that the tapered transmission line(s) need not have impedances which vary along their length in accordance with an exponential taper function. Any other suitable taper function, such as a Klopfenstein taper function, could instead be provided.

1. Impedance matching circuitry for adjusting an impedance match between a source impedance and a load impedance, the impedance matching circuitry comprising: tapered transmission line circuitry which comprises one or more tapered transmission lines coupled or couplable between the source impedance and the load impedance; and a controller in communication with the tapered transmission line circuitry and configured to adjust one or more impedances of the tapered transmission line circuitry to thereby adjust an impedance match between the source impedance and the load impedance.

2. Impedance matching circuitry according to claim 1 wherein the tapered transmission line circuitry comprises tuneable impedance circuitry, and the controller is configured to adjust one or more impedances of the tuneable impedance circuitry to thereby adjust an impedance match between the source impedance and the load impedance.

3. Impedance matching circuitry according to claim 2 wherein the tuneable impedance circuitry comprises one or more tuneable reactive components, and the controller is configured to adjust a reactance of one or more of the said tuneable reactive component(s) to thereby adjust the impedance match between the source impedance and the load impedance.

4. Impedance matching circuitry according to claim 2 wherein at least part of the tuneable impedance circuitry is incorporated into a said tapered transmission line.

5. Impedance matching circuitry according to claim 1 wherein the controller is configured to adjust one or more impedances of the tapered transmission line circuitry to thereby adjust an output impedance of the tapered transmission line circuitry such that it is closer to or equals a complex conjugate of the load impedance.

6. Impedance matching circuitry according to claim 1 further comprising an impedance mismatch sensor configured to detect an impedance mismatch between the source impedance and the load impedance, the impedance mismatch sensor being in communication with the controller.

7. Impedance matching circuitry according to claim 6 wherein the controller is configured to adjust the said one or more impedances of the tapered transmission line circuitry to thereby adjust the impedance match between the source impedance and the load impedance responsive to a determination by the controller from the impedance mismatch sensor of an impedance mismatch between the source impedance and the load impedance.

8. Impedance matching circuitry according to claim 1 wherein the tapered transmission line circuitry includes a tapered transmission line comprising a plurality of discrete sections coupled together.

9. Impedance matching circuitry according to claim 8 wherein each of a plurality of the said discrete sections is coupled to a respective tuneable impedance module of the tapered transmission line circuitry, the controller being configured to adjust an impedance of one or more of the said tuneable impedance modules to thereby adjust the impedance match between the source impedance and the load impedance.

10. Impedance matching circuitry according to claim 1 wherein the tapered transmission line circuitry comprises a first tapered transmission line connected in series with a second tapered transmission line, a first tuneable impedance module coupled to the first tapered transmission line and a second tuneable impedance module coupled to the second tapered transmission line, the controller being configured to adjust an impedance of a selected one of the first and second tuneable impedance modules to thereby adjust the impedance match between the source impedance and the load impedance.

11. Impedance matching circuitry according to claim 10 wherein the controller is configured to selectively adjust an impedance of the first tuneable impedance module to thereby adjust the impedance match between the source impedance and the load impedance in respect of signals propagating between the source and the load having a frequency within a first frequency range, and the controller is configured to selectively adjust an impedance of the second tuneable impedance module to thereby adjust the impedance match between the source impedance and the load impedance in respect of signals propagating between the source and the load having a frequency within a second frequency range different from the first frequency range.

12. Impedance matching circuitry according to claim 10 wherein the tapered transmission line circuitry further comprises tuneable impedance circuitry connected between the first and second tapered transmission lines.

13. Impedance matching circuitry according to claim 1 wherein the tapered transmission line circuitry comprises a quarter-wave transformer connected to a said tapered transmission line.

14. Circuitry comprising: a source having a source impedance; a load coupled to the source, the load having a load impedance; and impedance matching circuitry according to claim 1 coupled between the source impedance and the load impedance.

15. A method of adjusting an impedance match between a source impedance and a load impedance, the method comprising: coupling tapered transmission line circuitry comprising one or more tapered transmission lines between the source impedance and the load impedance; and adjusting one or more impedances of the tapered transmission line circuitry to thereby adjust an impedance match between the source impedance and the load impedance.
